(19) United States
(12) Patent Application Publication
(10) Pub. No.: US 2007/0119496 A1
(43) Pub. Date: May 31, 2007

(54) Photovoltaic cell

(75) Inventors: Marc A. Baldo, Cambridge, MA (US); Jonathan K. Mapel, Jamaica Plain, MA (US); Madhusudan Singh, Waltham, MA (US)

Correspondence Address: LOWRIE, LANDO & ANASTASI, RIVERFRONT OFFICE, ONE MAIN STREET, ELEVENTH FLOOR, CAMBRIDGE, MA, 02142, US

(73) Assignee: Massachusetts Institute of Technology, Cambridge, MA (US)

(21) Appl. No.: 11/290,625

(22) Filed: Nov. 30, 2005

(51) Int. Cl. H01L 31/00

(52) U.S. Cl. 136/252

(57) ABSTRACT

A photovoltaic cell and devices using the photovoltaic cell are provided. In certain examples, the photovoltaic cell may include a first material disposed on a first electrode and effective to generate an exciton upon absorption of electromagnetic energy. In some examples, the photovoltaic cell may also include a second material electrically coupled to the first electrode and separated from the first material, the second material effective to receive the generated exciton from the first material. In other examples, the photovoltaic cell may also include a second electrode electrically coupled to the second material and electrically coupled to the first electrode. Solar panels and power systems using the photovoltaic cell are also disclosed.

### GOVERNMENT FUNDING

Certain technology disclosed herein may have been developed, at least in part, under DARPA/AFOSR grant #F49620-02-1-0399 and support from a U.S. NDSEG fellowship. The United States government may have certain rights in the technology.

### FIELD OF THE TECHNOLOGY

Certain examples disclosed herein relate to photovoltaic cells. More particularly, certain examples disclosed herein relate to a photovoltaic cell whose optical properties and electrical properties may be individually optimized or tuned.

### BACKGROUND

Photovoltaic cells were developed by Bell Labs in 1950. Photovoltaic cells may be used to convert sunlight into electricity. A drawback of existing photovoltaic cells is that only a fraction of the sunlight's energy is converted into electricity because of the low efficiency of existing photovoltaic cells. Another drawback of photovoltaic cells is the high cost of the certain components which make up the photovoltaic cell. There remains a need for more efficient and cheaper photovoltaic cells.

### SUMMARY

Certain features, aspects and examples disclosed herein are directed to devices configured to generate electricity from light. More particularly, certain features, aspects and examples are directed to photovoltaic cells which are more efficient and cheaper to produce than a conventional photovoltaic cell. Additional features, aspects and examples are discussed in more detail herein.

In accordance with a first aspect, a photovoltaic cell comprising a first material disposed on a first electrode and effective to generate an exciton upon absorption of electromagnetic energy is disclosed. In certain examples, the photovoltaic cell may also include a second material electrically coupled to the first electrode and separated from the first material, the second material effective to receive the generated exciton from the first material. In some examples, the photovoltaic cell may also include a second electrode electrically coupled to the second material and electrically coupled to the first electrode. Additional features, aspects and examples of photovoltaic cells are discussed in more detail herein.

In accordance with another aspect, a photovoltaic cell comprising an electromagnetic energy absorbing component and a reaction center separate from the electromagnetic energy absorbing component and configured to receive energy from the electromagnetic energy absorbing component to generate a current is provided. In certain examples, the photovoltaic cell may also include a first conductive material and a second conductive material, in which the reaction center is between the first conductive material and the second conductive material, the first conductive material is between the electromagnetic energy absorbing component and the reaction center, and the first conductive material and the second conductive material are electrically coupled. In some examples, the photovoltaic cell may also include a reaction center that is configured to receive an exciton from the electromagnetic energy absorbing component and separate the exciton into positive and negative charge carriers such that a current may flow between the first conductive material and the second conductive material.

In accordance with an additional aspect, a solar panel comprising at least one photovoltaic cell comprising a first material disposed on a first electrode and effective to generate an exciton upon absorption of electromagnetic energy is disclosed. In certain examples, the at least one photovoltaic cell of the solar panel may also include a second material electrically coupled to the first electrode and separated from the first material, the second material being configured to receive the generated exciton from the first material. In some examples, the at least one photovoltaic cell of the solar panel may also include a second electrode electrically coupled to the second material and electrically coupled to the first electrode.

In accordance with another aspect, a solar panel comprising at least one photovoltaic cell comprising an electromagnetic energy absorbing component and a reaction center separate from the electromagnetic energy absorbing component and configured to receive energy from the electromagnetic energy absorbing component to generate a current is provided. In certain examples, the at least one photovoltaic cell of the solar panel may also include a first conductive material and a second conductive material, in which the reaction center is between the first conductive material and the second conductive material, the first conductive material is between the electromagnetic energy absorbing component and the reaction center, and the first conductive material and the second conductive material may be electrically coupled. In some examples, the at least one photovoltaic cell of the solar panel may also include a reaction center that is configured to receive an exciton from the electromagnetic energy absorbing component and separate the exciton into positive and negative charge carriers such that a current may flow between the first conductive material and the second conductive material.

In accordance with an additional aspect, a power system comprising at least one photovoltaic cell that includes a first material disposed on a first electrode and effective to generate an exciton upon absorption of electromagnetic energy is disclosed. In certain examples, the at least one photovoltaic cell of the power system may also include a second material electrically coupled to the first electrode and separated from the first material, the second material being configured to receive the generated exciton from the first material. In some examples, the at least one photovoltaic cell of the power system may also include a second electrode electrically coupled to the second material and electrically coupled to the first electrode.

In accordance with another aspect, a power system comprising at least one photovoltaic cell comprising an electromagnetic energy absorbing component and a reaction center separate from the electromagnetic energy absorbing component and configured to receive energy from the electromagnetic energy absorbing component to generate a current is provided. In certain examples, the at least one photovoltaic cell of the power system may also include a first conductive material and a second conductive material, in which the reaction center is between the first conductive material and the second conductive material, the first conductive material is between the electromagnetic energy absorbing component and the reaction center, and the first conductive material and the second conductive material are electrically coupled. In some examples, the at least one photovoltaic cell of the power system may also include a reaction center that is configured to receive an exciton from the electromagnetic energy absorbing component and separate the exciton into positive and negative charge carriers such that a current may flow between the first conductive material and the second conductive material.

In accordance with an additional aspect, a method of generating a current with a photovoltaic cell is provided. In certain examples, the method includes transferring an exciton produced from absorption of electromagnetic energy to a reaction center, and generating a current in the reaction center by separating positive and negative charge constituents of the transferred exciton. In some examples the exciton may be produced through energy absorption by an antenna.

These and other features, aspects, examples and uses of the technology disclosed herein are described in more detail below.

### BRIEF DESCRIPTION OF THE FIGURES

Certain examples are described below with reference to the accompanying figures in which:

FIG. 1 is an example of a device for generating a current, in accordance with certain examples;

FIG. 2 is a graph showing power efficiencies and power densities of certain commercial solar cells, in accordance with certain examples;

FIG. 3 is a graph of electrical power versus effective area for a photovoltaic cell, in accordance with certain examples;

FIG. 4 is a graph showing assembly costs of photovoltaic devices, in accordance with certain examples;

FIG. 5 shows the operating principles of an illustrative photovoltaic cell, in accordance with certain examples;

FIG. 6 shows an illustrative photovoltaic cell, in accordance with certain examples;

FIG. 7 shows an illustrative photosynthetic complex, in accordance with certain examples;

FIG. 8 is a graph of a photocurrent spectrum of a photovoltaic cell, in accordance with certain examples;

FIG. 9 is a graph of current-voltage characteristics of a photovoltaic cell, in accordance with certain examples;

FIGS. 10a and 10b are schematics of perpendicular excitation (FIG. 10a) and parallel excitation (FIG. 10b) in an illustrative photovoltaic cell, in accordance with certain examples;

FIG. 11a is a schematic of an illustrative photovoltaic cell, in accordance with certain examples;

FIG. 11b is a schematic of another illustrative photovoltaic cell, in accordance with certain examples;

FIG. 12 is a schematic of a photovoltaic cell with an optical element, in accordance with certain examples;

FIG. 13 is a schematic of a solar panel, in accordance with certain examples;

FIG. 14 is a schematic of a power system, in accordance with certain examples;

FIG. 15 is a schematic of a photovoltaic cell configuration that was used in a plane wave model, in accordance with certain examples;

FIG. 16 is a graph showing experimental and calculated efficiencies of a surface plasmon polariton in a plane wave model, in accordance with certain examples;

FIG. 17 is a graph showing illustrative guided surface plasmon polaritons (SPP) modes, in accordance with certain examples;

FIG. 18a is a graph showing that guided SPP mode (a) of FIG. 17 is the strongest in the reaction center, in accordance with certain examples;

FIG. 18b is a graph showing that guided SPP mode (b) of FIG. 17 is the strongest in the antenna, in accordance with certain examples;

FIG. 18c is a graph showing that guided SPP mode (c) of FIG. 17 is the strongest in the glass substrate, in accordance with certain examples;

FIGS. 19a and 19b are graphs showing decay rates of excitons into different modes, in accordance with certain examples;

FIG. 20 is a graph showing the overall efficiency for an exemplary photovoltaic cell with an external antenna, in accordance with certain examples;

FIG. 21 is a graph showing the quantum efficiency of two illustrative antennas, in accordance with certain examples;

FIG. 22 is a photograph of two illustrative antenna films, in accordance with certain examples; and

FIG. 23 is an absorption spectrum of an antenna film, in accordance with certain examples.

It will be recognized by the person of ordinary skill in the art, given the benefit of this disclosure, that the examples shown in the figures are not necessarily drawn to scale. Certain features or components, and the dimensions thereof, may have been enlarged, reduced or distorted to facilitate a better understanding of the illustrative aspects and examples disclosed herein. In addition, the use of shading, patterns, dashes and the like in the figures is not intended to imply or mean any particular material or orientation unless otherwise clear from the context.

### DETAILED DESCRIPTION

Examples of the technology disclosed herein may be used to convert energy from a photon into electrical energy. In certain examples, the optical function of the device may be separated from the electrical function of the device such that they are independent. In particular, the optical function of the device and the electrical function of the device may each be tuned or optimized such that higher energy transfer from an optical component to an electrical component may occur to increase the energy conversion efficiency of the device.

In accordance with certain examples, the devices, systems and methods disclosed herein generally use or involve two or more distinct components. One component or portion of the device is operative to absorb electromagnetic energy. Subsequent to absorption of the electromagnetic energy, an exciton may be formed in the first component. The first component re-radiates or otherwise transfers the exciton, or energy therefrom, into the second component of the device. The exact process used to transfer the energy may depend on the selected materials used in the first component and/or the second component. In certain examples, the first component re-radiates or non-radiatively transfers the exciton into guided optical modes created in the second component. This energy transfer may occur across an electrode that separates the first component and the second component. Such guided optical modes may be surface plasmon polaritons (SPP), for example. Energy in SPP modes can propagate perpendicularly to the incident light and may be efficiently absorbed by the second component. One significant benefit of this type of arrangement is that the materials and thicknesses of the materials for each component may be individually selected to provide for improved optical and electrical properties. For example, the thickness of the first component may be increased to promote increased absorption of incident electromagnetic energy without compromising the electrical performance of the second component. Similarly, the materials and thickness of the second component may be selected to increase the efficiency at which excitons are transferred from the first component without affecting the absorption performance of the first component. Another benefit of certain configurations is that more relaxed fabrication pathways may be used to provide, for example, flexible substrates making these devices suitable for cheaper integration with a variety of surfaces (for instance, plastics and glass windows). An additional benefit of certain configurations is that an increase in device power conversion efficiency coupled with low production costs allow the possibility of cheap and intensive harvesting of solar power for powering a variety of personal and public electrical and electronic equipment that could free society from dependence on uncertainties of exhaustible domestic and foreign energy sources such as oil. Additional configurations for devices such as photovoltaic cells, solar panels and power systems are discussed in more detail herein.

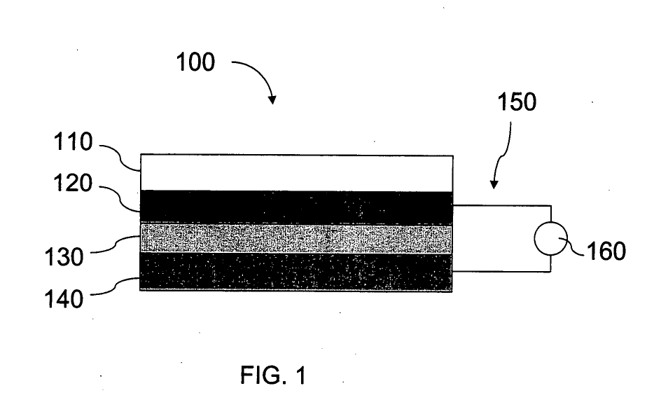

In accordance with certain examples, a device comprising a first material selected for its electromagnetic energy absorption properties, a second material separated from the first material and electrically coupled to the first material, and a pair of electrodes electrically coupled to the second material is disclosed. Referring to FIG. 1, a device 100 comprises a first material 110 disposed on an electrode 120. The device 100 also comprises a second material 130 disposed between the electrode 120 and an electrode 140. The electrodes 120 and 140 are electrically coupled to the second material 130 such that as positive and negative charge carriers are separated by the second material 130, a current may be generated in an external circuit 150, which may be, for example; electrically coupled to a load 160.

In certain examples, the first material may be selected from materials that can absorb light emitted from a source, such as the sun. In particular, the first material is typically a non semi-conductor material which includes one or more chromophores that can absorb light in the ultraviolet, visible and/or infrared regions. In some examples, the chromophore may have an absorption maximum in the wavelength range of about 200 nm to about 2000 nm, more particularly, about 400 run to about 1100 nm, e.g., about 400 nm to about 700 nm.

Unlike a conventional photovoltaic cell, the first material of the devices disclosed herein may not be directly involved in conversion of excitons into positive and negative charge carriers. In a conventional photovoltaic device, a photoactive semiconducting element is responsible for the primary three functions of the device. These functions are: (a) the transduction of electromagnetic radiation into excited atomic or molecular states, (b) the transport of the excited state to a reaction center to be dissociated into its constituent electron and holes, and (c) the transport of the mobile charges to conductive contacts to be utilized in an external circuit. A single material typically performs all three functions in most photovoltaic devices in production or being developed. The performance of the device therefore relies on both the optical and electrical properties of a single semiconductor or group of stacked semiconducting layers. In many instances, the electrical and optical objectives are mutually contradictory, giving rise to design and fabrication difficulties in photovoltaic devices. In contrast, certain embodiments of the devices disclosed herein separate the absorption and electrical properties such that each may be individually tuned or optimized to enhance performance of the device.

In accordance with certain examples, the first material may be one or more materials including, but not limited to, quantum dots, biologically derived light harvesting compositions, e.g., phycobiliproteins and phycobilisomes present in cyanobacteria and red algae, dyes, such as inorganic and/or organic dyes, and films of organic dyes and inorganic dyes. In other examples, the first material may include metal nanoparticles embedded in a solid-state semiconductor matrix. Other materials suitable for use in the first component include, but are not limited to, compositions comprising two or more conjugated aromatic rings and J-aggregates (dipole layers exhibiting long-range order). Additional materials suitable for use in the first material will be readily selected by the person of ordinary skill in the art, given the benefit of this disclosure.

In accordance with certain examples, the second material of the device may be selected from a material that can convert a transferred exciton into positive and negative charge carriers. In some examples, the second material may be selected from one or more semiconducting materials including, but not limited to, materials that include Si, GaAs, GaN and SiC. In certain examples, other materials such as, for example, perylene and its derivatives, fullerenes and its derivatives, pthalocyanines and their derivatives, semiconducting conjugated polymers and their derivatives, and biological reaction centers, e.g., bacterial reaction centers present in photosynthetic microorganisms may also be used. Additional suitable materials will be readily selected by the person of ordinary skill in the art, given the benefit of this disclosure.

In accordance with certain examples, the electrodes of the device may include conductive materials and non-conductive materials. Illustrative conductive materials include, but are not limited to, carbon, metals such as platinum, gold, copper or other conductive transition metals, conductive ceramics, metal alloys, heavily-doped transparent semiconductors such indium tin oxide, heavily doped semiconductors such as doped polysilicon, carbon nanotubes, and semiconducting nanowires. It will be within the ability of the person of ordinary skill in the art, given the benefit of this disclosure, to select suitable materials for use in the electrodes of the devices disclosed herein.

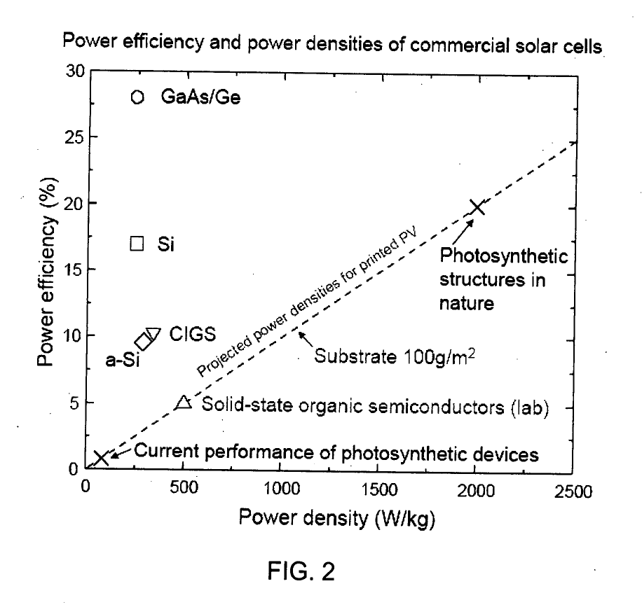

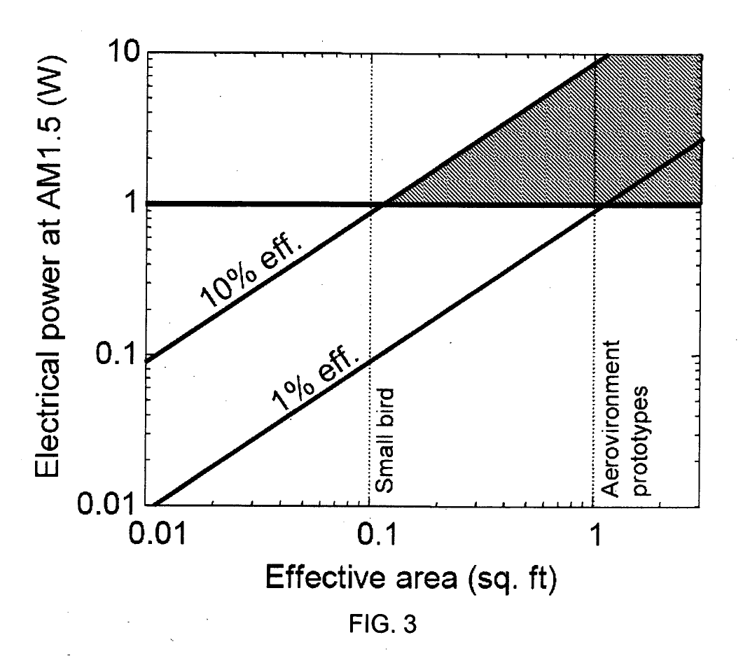

In accordance with certain examples, a photovoltaic cell is disclosed. To understand better the advantages and benefits of the photovoltaic cells disclosed herein, a comparison to the conventional photovoltaic devices is now discussed. Certain semiconductor photovoltaic devices may exhibit very high power conversion efficiencies, but they are not suitable for low-cost or weight-critical applications. This problem originates in the high temperature processes required in the fabrication of crystalline and poly-crystalline covalently bonded semiconductors. These processes preclude the use of light weight but low temperature flexible substrates such as polyimide or Kapton. A technology that is compatible with these plastics but exhibits high power conversion efficiencies of greater than 20% could achieve power densities of 2 kW/kg, revolutionizing energy generation in a variety of remote area and autonomous applications, such as micro aerial vehicles. Referring to FIG. 2, a graph of power efficiency versus power density shows that significant power advantages could be gained by using photosynthetic cells to convert light into energy. Referring to FIG. 3, a graph of electrical power versus effective area shows that power conversion efficiencies of at least about 10% would be desirable to power devices such as micro aerial vehicles.

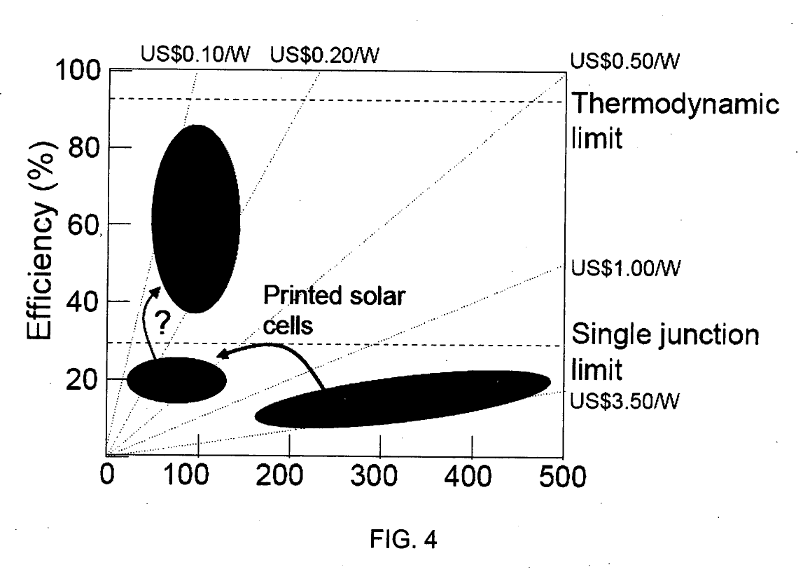

There is still an outstanding need to provide better manufacturing methods to reduce assembly costs of photovoltaic devices (see FIG. 4). To reduce the costs of photovoltaic cells, much effort has been expended in the development of thin film photovoltaics. In these cells, the semiconductor is deposited on the substrate and then either utilized directly as an amorphous semiconductor, or it may be recrystallized after deposition into a polycrystalline film. Ideally, a low cost manufacturing process such as roll-to-roll printing may be employed to increase throughput. Typically, it is difficult to deposit a uniformly crystalline thin film, thus thin film photovoltaic cells have greater defect densities than their crystalline counterparts. In typical covalent semiconductors, the photogenerated carriers are delocalized and excitons are uncommon since their binding energy is weak. But weak intermolecular van der Waals' interactions help localize charge carriers and excited states in organic semiconductors. Exciton effects are dominant, and the exciton binding energy may be on the order of 1 eV. Typical internal electric fields at pn junctions and Schottky barriers are unlikely to ionize excitons with large binding energies. Thus, designers of organic photovoltaic cells have relied on interfaces to dissociate excitons instead of any internal electric fields. See Tang, C. W., “Two layer organic photovoltaic cell,” Applied Physics Letters 48, 183 (1986).

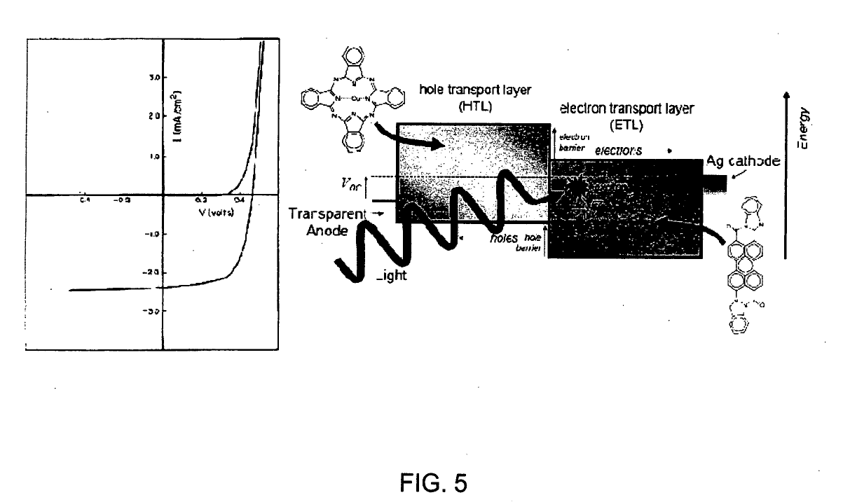

The operating principle of such illustrative cells is shown in FIG. 5. The material with the largest electron affinity is referred to as the acceptor, and the other material is referred to as the donor. Photocurrent generation proceeds by the absorption of an incident photon in the donor or acceptor layers. Absorption creates an exciton, a bound electron hole pair, that can migrate through either the donor or acceptor layers until reaching the interface between the two. At the interface, the energetic offset between the highest occupied molecular orbital in the acceptor and the lowest unoccupied molecular orbital in the donor initiates exciton dissociation, resulting in separated electrons and holes. Like any solar cell, organic photovoltaic cells must absorb as much light as possible. But the choice of organic semiconductors imposes two drawbacks on optical absorption. First, few organic materials absorb at wavelengths greater than about 900 mn, effectively wasting this portion of the solar spectrum. Second, excitons in organic semiconductors have a limited lifetime, and hence a limited diffusion length. If the exciton dissociation interface is not within an exciton diffusion length, then the exciton will decay and its energy is wasted.

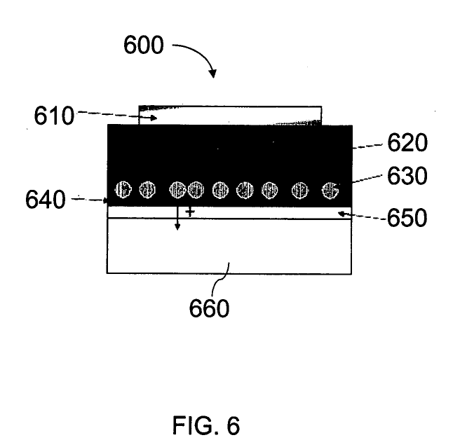

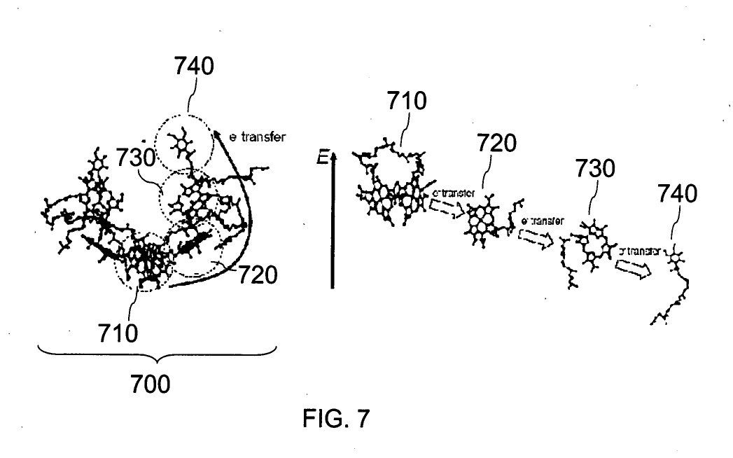

In accordance with certain examples, photosynthetic centers, or equivalents thereof, may be used in the electromagnetic energy absorbing component of the devices disclosed herein to absorb electromagnetic energy. Over two billion years of evolutionary adaptation have optimized the functionality of biological photosynthetic complexes. Plants and photosynthetic bacteria, for example, contain protein molecular complexes that harvest photons with nearly optimum quantum yield and an expected power conversion efficiency exceeding 20%. The functionality of photosynthetic centers may be tested by fabricating solid state photodetectors and photovoltaic devices, using complexes isolated, for example, from spinach leaves or photosynthetic bacteria. The internal quantum efficiency of the first generation of devices is estimated to be about 12% or greater. See Das, et al., “Integration of Photosynthetic Protein Complexes in Solid-State Electronic Devices,” Nano Letters 4, 1079 (2004). Stabilizing the complexes in an artificial environment should provide successful device integration. For example, electronic integration of devices have been achieved (see FIGS. 6 and 7) by stabilizing an oriented, self-assembled monolayer of photosynthetic complexes using novel surfactant peptides, and then depositing an organic semi-conducting protective coating as a buffer to prevent damage to the complexes when depositing the top metal contact. FIG. 6 shows the structure of a solid-state device incorporating the reaction center from Rhodobacter sphaeroides. The device 600 includes a contact 610, e.g., a silver contact, that is electrically coupled to an organic charge transport layer 620. A self-assembled monolayer that functions as a reaction center 630 is in contact with a buffer layer 640, which is in contact with a transparent conductive contact 650. The transparent conductive contact 650 is in contact with a substrate 660, e.g., glass. During functioning of device 600, light may be absorbed in the reaction center 630. The reaction center may convert the energy into constituent positive and negative charges. In this illustrative example, negative charges migrate towards the contact 610 and positive charges migrate towards the contact 650 such that a current can be generated using the absorbed light

FIG. 7 shows a model of the internal molecular circuitry of an illustrative photosynthetic bacterial reaction center with the protein scaffold removed for clarity, as described in Ermler et al., Structure, Vol. 2, pg 925-936 (1994). The photosynthetic complex 700 is only a few nanometers top-to-bottom. After photoexcitation, an electron is transferred from the special pair, P, to the quinone, Q_{L}, in complex 700. In particular, this energy transfer process may occur stepwise through the complex as energy is transferred from a higher energy moiety to a lower energy moiety of the complex. For example, special pair 710 can absorb energy from incident light. The energy may be transferred to a second moiety 720, e.g., a bacteriochlorophyll. The second moiety 720 may transfer energy to a third moiety 730, e.g., a bacteriopheophytin. The third moiety 730 may transfer energy to a fourth moiety 740, e.g., a quinone. The process occurs rapidly within the complex, e.g., within about 200 ps, at nearly 100% quantum efficiency, and results in a 0.5V potential across the complex.

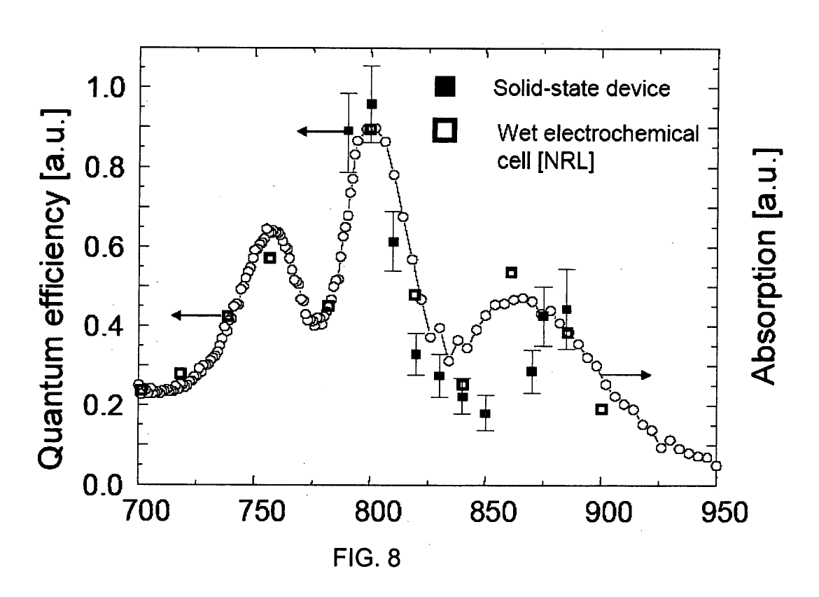

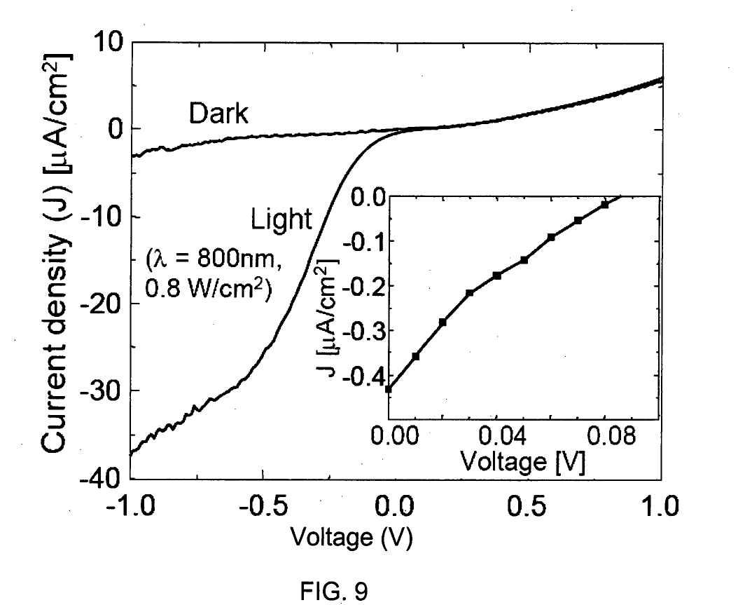

Successful integration of a photosynthetic complex is demonstrated by comparisons of the absorption spectrum and photocurrent spectra in FIGS. 8 and 9. In particular, the photocurrent spectrum of a cell (FIG. 8) containing a photosynthetic reaction center has the same general shape/pattern as the absorption spectrum of the complex in solution. The current-voltage characteristics of the cell (FIG. 9) confirms photovoltaic activity. In particular, when the cell is exposed to light, both the current density and the voltage increase. Initial results demonstrate the functionality of biological materials in solid state devices. However, photovoltaic performance was limited due to low light absorption of the monolayers of photosynthetic structures.

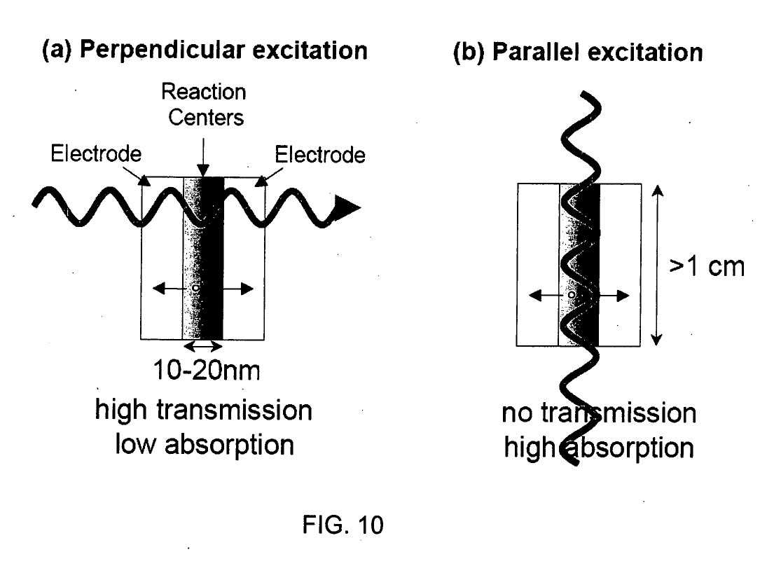

In accordance with certain examples, plasmon enhanced absorption may be used in the photovoltaic cells disclosed herein to improve efficiency. The efficiency of solar cells based on molecular materials (synthetic or photosynthetic components) is presently limited by a fundamental tradeoff in that to absorb as many photons as possible, thick organic semi-conducting films should be used, but many of the excitons in thick films are wasted, because they are absorbed too far from a dissociation interface. This tradeoff holds for solar cells fabricated from synthetic organic materials, as well as for solid state solar cells based on photosynthetic reaction centers from plants and bacteria. Although photosynthetic reaction centers possess perhaps the best electrical properties of any organic charge separating structure, a single photosynthetic complex itself absorbs very little light. But as shown in FIGS. 10a and 10b, if light is directed parallel to the electrodes (FIG. 10b), much higher absorption efficiencies can be achieved. In particular, incident light that is parallel to the electrodes can provide high absorption and little transmission in the reaction center, whereas incident light that is perpendicular to the electrodes can provide low absorption and high transmission in the reaction center. It may be desirable, for example, to include one or more optical elements, such as lenses, gratings, etc., with a photovoltaic cell, such that light is incident on the cell in a plane that is substantially parallel to the plane of the electrodes. It will be within the ability of the person of ordinary skill in the art, given the benefit of this disclosure, to design a suitable photovoltaic cell operative to receive incident light that is parallel to the electrodes of the photovoltaic cell.

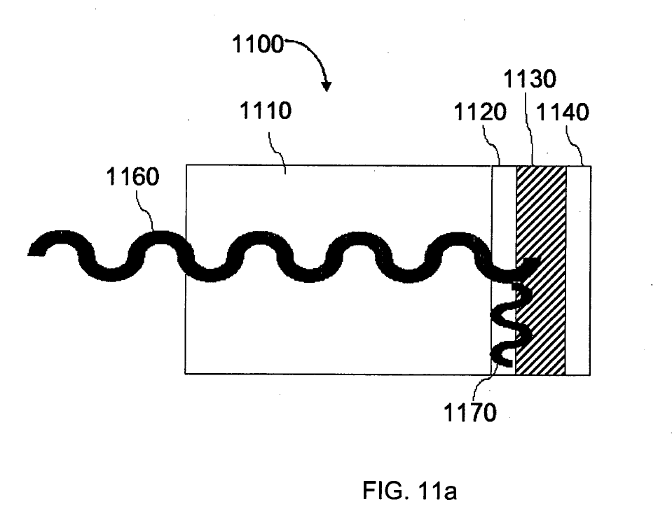

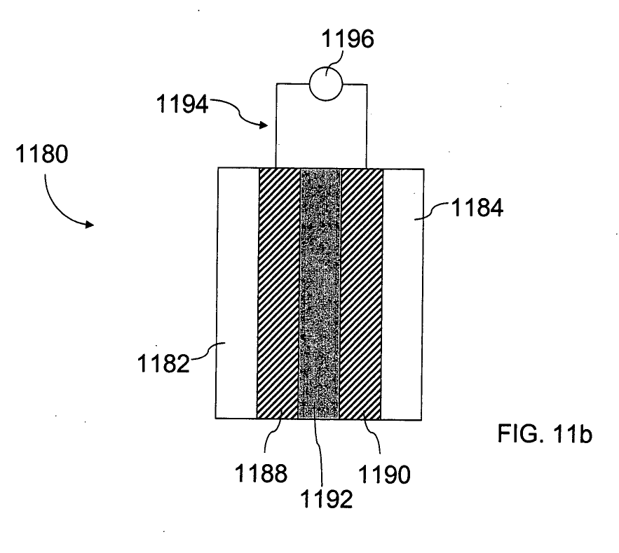

In accordance with certain examples and based on the above, a photovoltaic cell comprising an electromagnetic energy absorbing component and a reaction center separate from the electromagnetic energy absorbing component and configured to receive energy from the electromagnetic energy absorbing component to generate a current is disclosed. As used herein, the term “reaction center” refers to the area or portion of the device that generates a charge. The electromagnetic energy absorbing component is also referred to in some instances herein as an antenna. While the functions of the reaction center and the electromagnetic energy absorbing component are separate and in certain embodiments different materials are used in the antenna and the reaction center, the reaction center and the antenna may be located on the same substrate, e.g., a planar substrate, or in close proximity to each other, e.g., they may both be disposed between two electrodes. Referring to FIG. 11a, a photovoltaic cell 1100 comprises an antenna 1110 disposed on an electrode 1120. A reaction center 1130 is disposed between the electrode 1120 and an electrode 1140. In the illustrative embodiment shown in FIG. 11a, the antenna 1110 and the reaction center 1130 are physically separated from each other by the electrode 1120, e.g., they are not in direct contact. It will be recognized by the person of ordinary skill in the art, given the benefit of this disclosure, that the exact thickness of the antenna may vary depending on the electromagnetic energy absorptive properties of the material(s) used in the antenna. In certain examples, the thickness of the antenna 1110 may vary from about 25 nm to about 500 nm, more particularly from about 50 nm to about 350 nm, e.g., about 100 nm to about 200 nm. It will also be recognized by the person of ordinary skill in the art, given the benefit of this disclosure, that the exact thickness of the reaction center may vary depending on the electrical properties of the material(s) used in the reaction center. In certain examples, the thickness of the reaction center 1130 may vary from about 1 nm to about 40 nm, more particularly from about 5 nm to about 30 nm, e.g., about 10 nm to about 20 nm. Additional thicknesses for the antenna and the reaction center will be readily selected by the person of ordinary skill in the art, given the benefit of this disclosure. Illustrative materials for including in the antenna include, but are not limited to quantum dots, biologically derived light harvesting compositions, e.g., phycobiliproteins and phycobilisomes present in cyanobacteria and red algae, dyes, such as inorganic and/or organic dyes, films of organic dyes, films of inorganic dyes, metal nanoparticles embedded in a solid-state semiconductor matrix, two or more conjugated aromatic rings and J-aggregates. Illustrative materials for including in the reaction center include, but are not limited to Si, GaAs, GaN and SiC. Perylene and its derivatives, fullerenes and its derivatives, pthalocyanines and their derivatives, semiconducting conjugated polymers and their derivatives, and biological reaction centers, e.g., bacterial reaction centers present in photosynthetic microorganisms may also be used in the reaction center. Additional materials and compositions for use in each of the antenna and the reaction center will be readily selected by the person of ordinary skill in the art, given the benefit of this disclosure.

During operation of the photovoltaic cell 1100, incident electromagnetic energy 1160, e.g., light, may be absorbed by the antenna 1110. An exciton may be formed in the antenna 1110. The antenna 1110 then may re-radiate or non-radiatively transfer the exciton, or energy therefrom, into one or more guided optical modes, e.g., surface plasmon polaritons, created in the electrode 1120/reaction center 1130/electrode 1140 assembly thereby transferring the energy across the electrode 1120 to the reaction center 1130. Energy 1170 from the surface plasmon polaritons may propagate perpendicularly to the incident electromagnetic energy 1160. To provide an efficient photovoltaic cell, it is desirable that the energy absorption process in the antenna 1110 be as efficient as possible and that the energy transfer process from the antenna 1110 to the reaction center 1120 be as efficient as possible as well. In certain examples, because the absorption function and the electrical function of the photovoltaic cell 1100 have been separated, the thickness of the antenna 1110 can be increased to provide for increased absorption without comprising the electrical performance of the photovoltaic cell 1100. It will be within the ability of the person of ordinary skill in the art, given the benefit of this disclosure, to design suitable photovoltaic cells for an intended use.

In accordance with certain examples, a photovoltaic cell may include two or more antennae. For example and referring to FIG. 11b, a photovoltaic cell 1180 comprises a first antenna 1182 and a second antenna 1184. The first antenna 1182 is disposed on a first electrode 1188, and the second antenna 1184 is disposed on a second electrode 1190. A reaction center 1192 is disposed between the first electrode 1188 and the second electrode 1190. The electrodes 1188 and 1190 are electrically coupled to the reaction center 1192 such that as positive and negative charge carriers are separated by the reaction center 1192, a current may be generated in an external circuit 1194, which may be, for example, electrically coupled to a load 1196. Each of the first antenna 1182 and the second antenna 1182 may independently act to absorb incident light and transfer an exciton, or energy therefrom, into the reaction center, as discussed herein.

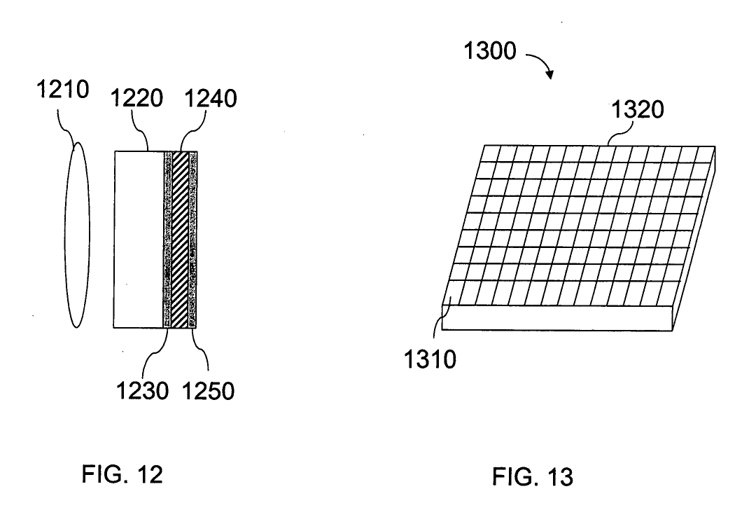

In accordance with certain examples, an optical element may be used with the devices disclosed herein. In certain examples, the optical element may be used to select a wavelength, or a wavelength range, of light for absorption by the antenna of the device. Referring to FIG. 12, an optical element 1210 is shown positioned near an external surface of an antenna 1220. The optical element may be in contact with the antenna 1220 or may be positioned a suitable distance from the surface of the antenna 1220. The optical element 1210 may function to select a wavelength, control the direction at which light is incident on the antenna surface, focus light beams at a particular area or point in the antenna, or may provide other selected optical responses as will be recognized by the person of ordinary skill in the art, given the benefit of this disclosure. Optical element 1210 can provide many different functions and is not limited to the illustrative functions disclosed herein. Once light is absorbed by the antenna 1220, energy may be transferred into the reaction center 1240. Electrodes 1230 and 1250 may be electrically coupled to the reaction center 1240 to provide a current. Illustrative optical elements include, but are not limited to, lenses, prisms, gratings, filters, anti-reflective coatings and the like. Additional optical elements will be readily selected by the person of ordinary skill in the art, given the benefit of this disclosure.

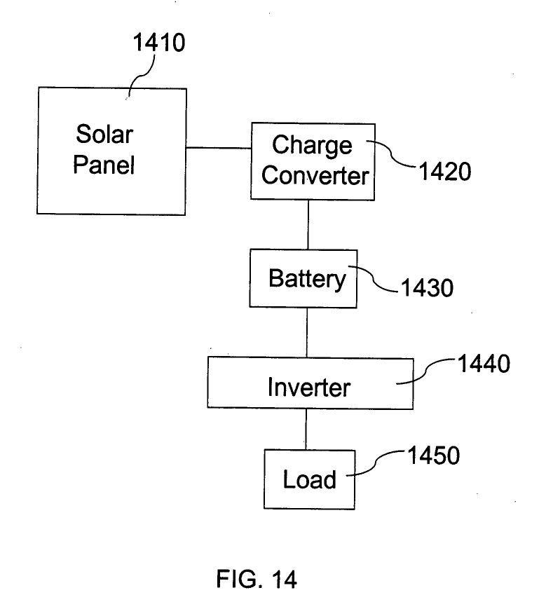

In accordance with certain examples, a solar panel comprising a plurality of photovoltaic cells is disclosed. In certain examples, at least one of the plurality of photovoltaic cells comprises a first material, e.g., in an antenna, selected for its energy absorbing properties, a second material, e.g., in a reaction center, separated from the first material and selected for its electrical properties, and a pair of electrodes electrically coupled to the second material. For example and referring to FIG. 13, a solar panel 1300 comprises a plurality of photovoltaic cells, such as photovoltaic cells 1310 and 1320. In this illustration, photovoltaic cell 1310 is configured similar to the photovoltaic cell shown in FIG. 11a. In certain examples, the solar panel may include an array of photovoltaic cells with at least one member of the array configured similar to the photovoltaic cells described herein. In some examples, each member of the array comprises a photovoltaic cell as described herein. The individual members of the array are typically electrically coupled to a lead or wire, e.g., in a circuit, to provide a desired amount of power, e.g., 5 Watts, 10 Watts, 20 Watts, 50 Watts or more, to a load. The exact dimensions of the solar panel may vary depending on the intended use, site space, the desired power output and the like. In certain examples, the solar panel is about 5 inches to about 25 inches wide by about 10 inches to about 48 inches long by about 0.5 inches to about 3 inches thick. In certain examples, the solar panel may include one or more hinges so that the panels may be folded for transport or to reduce the amount of space occupied by the panel when not in use. Additional sizes for a solar panel will be readily selected by the person of ordinary skill in the art, given the benefit of this disclosure.

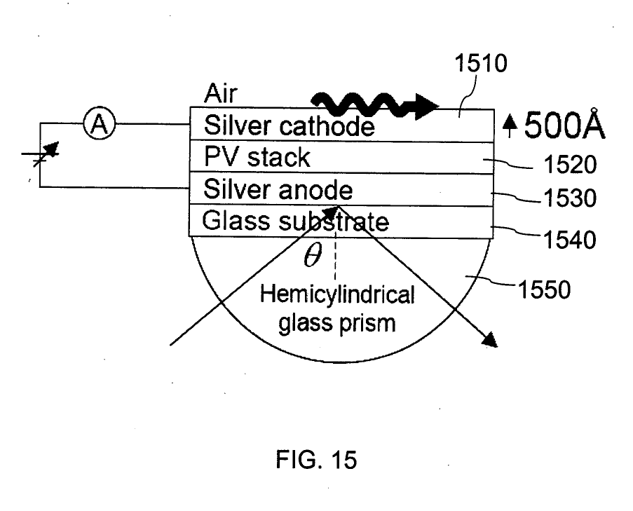

In accordance with certain examples, a power system comprising at least one photovoltaic cell as disclosed herein is provided. Referring to FIG. 14, a power system 1400 comprises a solar panel 1410, which includes at least one photovoltaic cell as described herein, a charge converter 1420, an optional battery 1430 (or batteries) to store the power produced by the power system, and an optional inverter 1440 in the case where it is desirable to convert DC voltage to AC voltage for use by a load 1450. The charge converter 1420 functions to make sure the battery 1430 remain properly charged. In the case where the solar panel provides power directly to a device, such as a stove, for example, the charge converter may be omitted. The inverter functions to switch DC current back and forth to produce an alternating current. Illustrative inverters include sine wave inverters and modified sine wave inverters. In instances where DC voltage is used, e.g., in recreational vehicles, automobiles, etc., the inverter may be omitted. Suitable transformation, filtering, stepping and the like may be performed such that an acceptable waveform is outputted by the inverter. The power system may also include automatic or manual transfer switches (not shown). For example, where the power system is used as a back-up power system, an automatic transfer switch can sense when the primary power system fails and can switch on the back-up power system in a safe manner to prevent current flow back into the failed power system.

In certain examples, the power system may be used to generate primary power for use by a home, a mobile vehicle (e.g., a car, ship or a recreational vehicle), unmanned aircraft (e.g., satellites, remote-controlled drones and the like), cellular phone towers, satellite towers, remote switches and lights used in transportation systems (e.g., railroads, airports, shipping facilities, etc.) and other suitable devices that may benefit from the use of solar power. In some examples, the power system may be used to co-generate power, e.g., may be used along with existing power grids, may be used along with turbine generated power, hydro-electric generated power, nuclear generated power and the like. Additional uses of power systems that include at least one photovoltaic cell as disclosed herein will be readily selected by the person of ordinary skill in the art, given the benefit of this disclosure.

In accordance with certain examples, a method of making a photovoltaic cell is provided. In certain examples, the method includes disposing an electroactive material between two conductive materials configured as electrodes. The method may also include disposing a photoactive material on at least one of the electrodes of the electrode pair or both of the electrodes of the electrode pair. The exact methods and devices used to dispose the photoactive and electroactive material may vary depending on the desired thickness, the selected materials and the intended use of the overall device. In certain examples, the materials may be sputtered, spin-coated or otherwise deposited on the surface of an electrode to a desired thickness. Illustrative techniques include physical vapor deposition, chemical vapor deposition, ion beam sputtering, ion beam plating, discharge sputtering, evaporation and the like.

In some examples, the photovoltaic cell may be disposed on a substrate, such as a plastic or a glass, to provide structural support for the various components of the photovoltaic cell. In particular, layers may be disposed on a glass substrate to produce a photovoltaic cell. For example, a first conductive layer may be disposed on the glass substrate to provide a first electrode followed by an electroactive material configured to function as a reaction center. A second conductive layer may be disposed on the electroactive material to provide a second electrode. A photoactive material configured to function as an antenna may be disposed on the second conductive layer. The thickness of each layer may vary depending on, for example, the selected material, the desired efficiency and the intended use of the photovoltaic cell. Illustrative thicknesses are discussed above and additional thicknesses will be readily selected by the person of ordinary skill in the art, given the benefit of this disclosure. An optional protective coating may be disposed on the photoactive material to enable the photovoltaic cell to withstand environmental forces, such as heat, ice, hail and the like. Additional features to enable the photovoltaic cell to function in a selected environment will be readily selected by the person of ordinary skill in the art, given the benefit of this disclosure.

In accordance with certain examples, a method of generating a current using a photovoltaic cell is provided. In certain examples, the method includes transferring an exciton produced from absorption of electromagnetic energy to a reaction center, and generating a current in the reaction center by separating positive and negative charge constituents of the transferred exciton. In some examples, the method may also include configuring the reaction center to receive energy from one or more guided surface plasmon polaritons modes of the exciton. In other examples, the method may also include absorbing the electromagnetic energy with an antenna that converts the electromagnetic energy into an exciton. Additional steps that may be useful in generating a current in a photovoltaic cell will be recognized by the person of ordinary skill in the art, given the benefit of this disclosure.

Certain specific examples are described below to illustrate further the novel technology disclosed herein.

### EXAMPLE 1

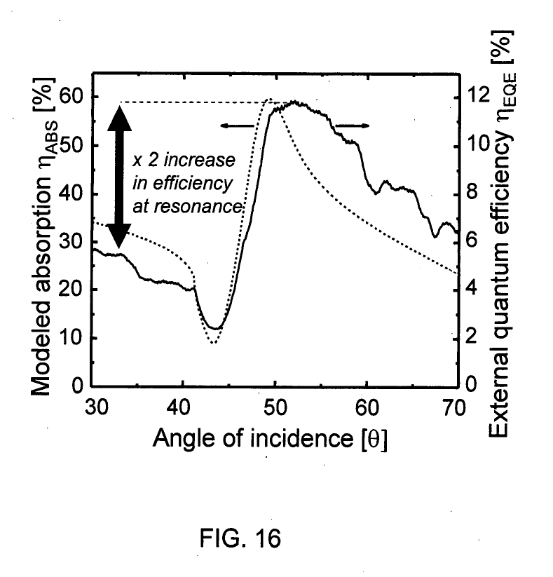

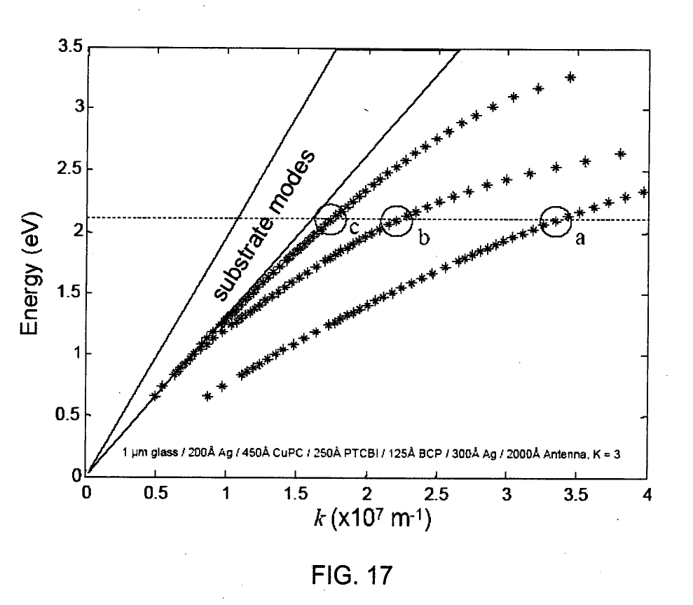

A plane wave model was used to predict the efficiency of surface plasmon polariton (SPP) absorption by thin reaction centers. The model used was based on Soole, J. B. D., et al. “Electromagnetic resonance enhanced photoabsorption in planar metal-oxide-metal tunnel junction detectors” J. Appl. Phys. 61, 5, 2002-2009. (1987). Referring to FIG. 15, a configuration known as a Kretschmann configuration was used in the plane wave model. In the Kretschmann configuration, light of varying angle of incidence is illuminated upon the cell and both the reflected optical intensity and photocurrent is recorded. The photovoltaic cell comprises a silver cathode 1510, a reaction center 1520, a silver anode 1530, a glass substrate 1540 and a hemi-cylindrical prism 1550. The surface of the silver cathode 1510 is exposed to air. A comparison of theory (dotted line) to experimental data (FIG. 16) shows an increase in efficiency by a factor of about 2. This result is consistent with enhancing the efficiency of reaction centers using incident radiation coupled into a guided surface plasmon polariton. This result is also consistent with low exciton diffusion losses, low optical absorption and very high quantum efficiency.

### EXAMPLE 2

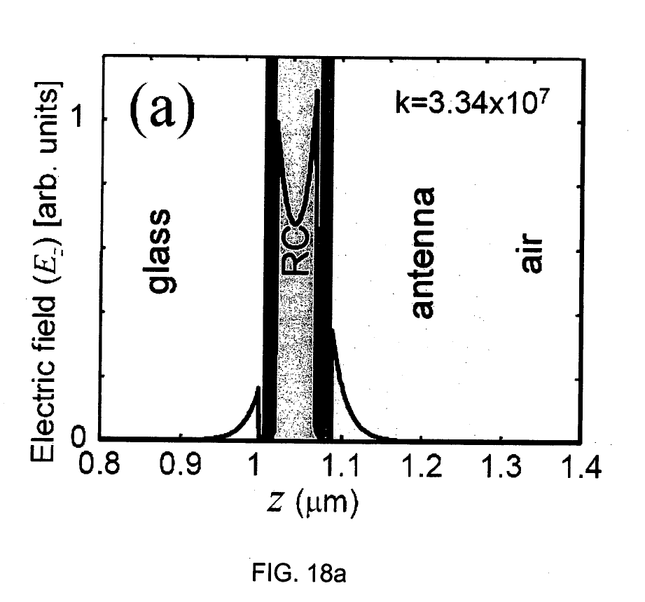

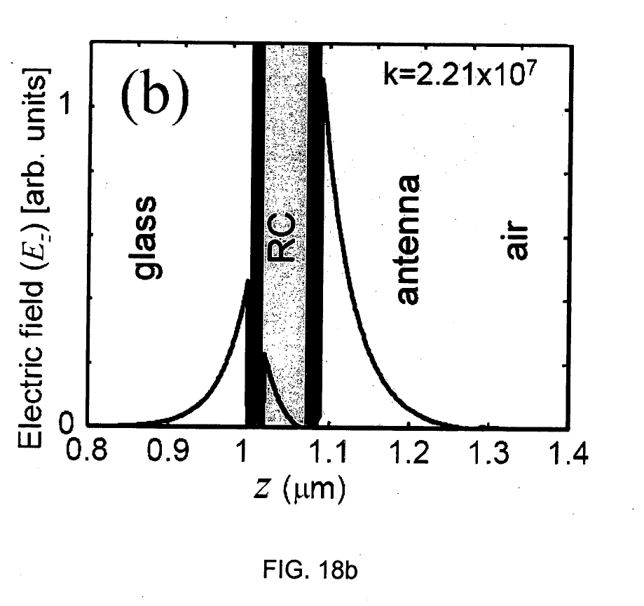

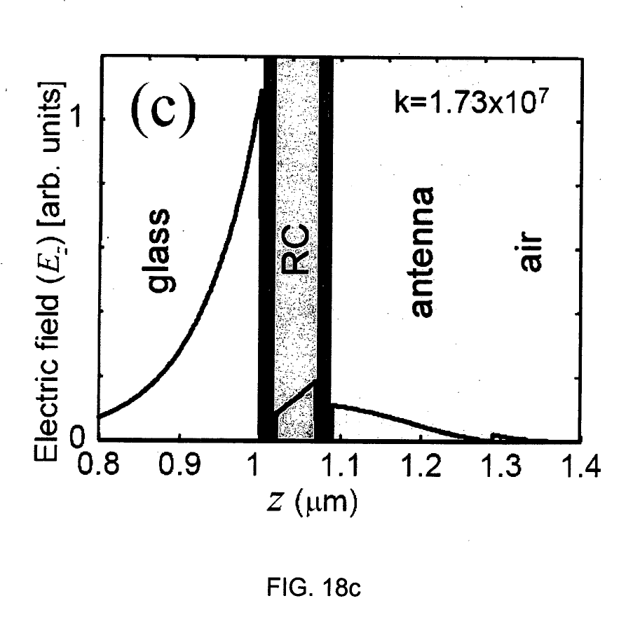

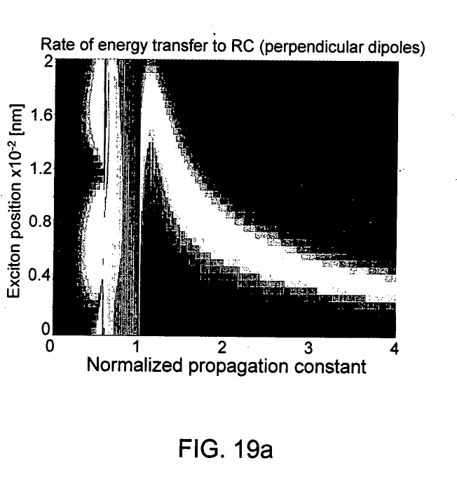

A second model involving a more sophisticated Green's function technique was used to predict the coupling of excited states in the antenna to guided modes in the reaction center stack. The second model was based on Chance et al., “Molecular fluorescence and energy transfer near interfaces”, Adv. Chem. Phys. 37, 1, p1-65 (1978) & Hartman et al., J. Chem Phys. 110, 4, p2189-2194. (1999). FIG. 17 shows the dispersion relation for three illustrative guided SPP modes calculated using the second model. These modes were calculated in the limit of lossless electrodes. The exemplary guided SPP modes shown in FIG. 17 propagated parallel to the electrode plane in a photovoltaic cell with an external antenna. Three guided modes were selected in this structure and the intensity profile of each is shown in FIGS. 18a-18c. The strength of the mode corresponds to the amplitude of the electric field (shown in FIGS. 18a-18c). The maximum of the electric field occurs in the substrate, the reaction center, or the antenna. Referring to FIG. 18a, mode (a) is the strongest in the reaction center. Referring to FIG. 18b, mode (b) is the strongest in the antenna. Referring to FIG. 18c, mode (c) is strongest in the glass substrate. All the guided modes had significant overlap with the charge generation layers sandwiched between the metal electrodes. For the mode labeled (b) in FIG. 17 and shown in FIG. 18b, the SPP centered on the silver/antenna interface has by far the highest intensity in the antenna, which indicates that the antenna should preferentially couple with mode (b).

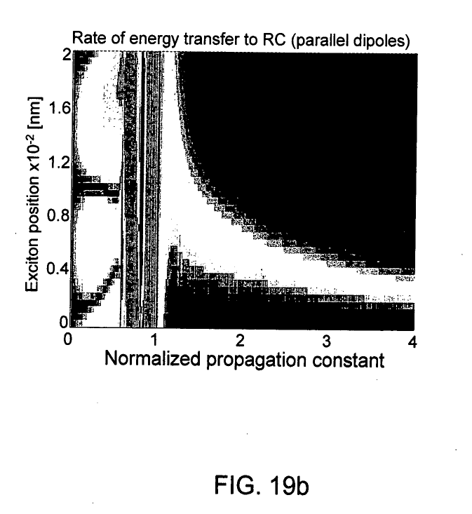

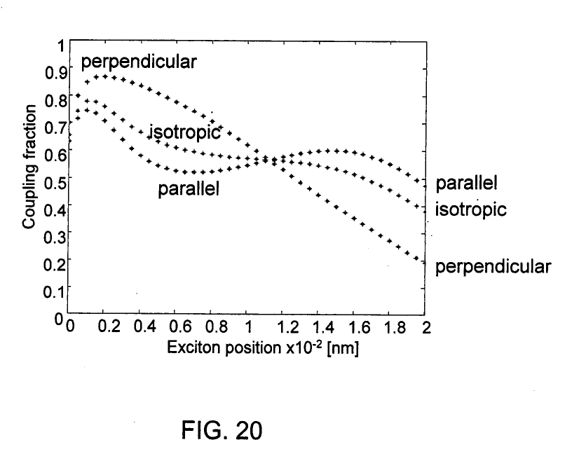

The rate of power transfer from the antenna to the reaction center was calculated from the Poynting vector, as calculated by the Green's function technique of Chance et al. The results are shown in FIGS. 19a and 19b. Excitons with transition dipoles oriented perpendicular and parallel to the stack were considered separately. If the molecules are randomly oriented, the transition dipoles will be roughly ⅓ perpendicular and ⅔ parallel. The decay of antenna excitons with transition dipoles oriented perpendicular to the stack is dominated by energy transfer to a surface plasmon with normalized propagation constant u=1.2. This corresponds to mode (b) in FIG. 17. In particular, excitons with perpendicular transition dipole moments predominantly decay by Forster transfer to the SPP mode (b). Modes (a) and (c) are also visible, but much weaker. Energy transfer for parallel dipoles is dominated by reradiation into waveguide modes with u<1. The overall efficiency for a photovoltaic cell with an external antenna, as described herein, is shown in FIG. 20. The efficiency was calculated directly from the Poynting vector in the second model. The structure used in the calculation was assumed to be a glass/250 Å Ag/500 Å reaction center (modeled by copper phthalocyanine)/250 Å Ag/2000 Åantenna and n was assumed to be about 1.7 (air). It was also assumed that an antenna with a free space photoluminescent efficiency of 70% and emission at λ=620 nm was used. For antennas comprised of molecules with perpendicular transition dipole moments, the efficiency of energy transfer to the reaction center would typically be greater than 50%. Exciton position was measured from the first (Ag) electrode, and propagation constant was normalized to free space value. In FIGS. 19a and 19b, values greater than one correspond to non-radiative energy transfer e.g., energy transfer into surface plasmon modes. There were higher rates of energy transfer from dipoles close to the Ag electrode with decreasing efficiency further from the Ag electrode. It should be noted that molecules with transition dipoles oriented perpendicularly absorb the least incident radiation. An ideal antenna should transfer energy from parallel dipoles, which have the highest absorption, to the reaction center.

### EXAMPLE 3

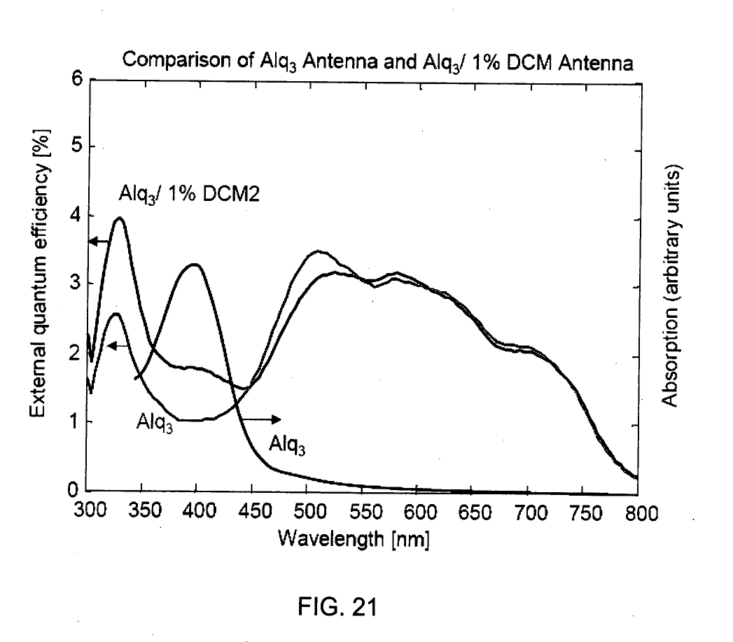

Energy transfer from an antenna was experimentally demonstrated. Two antennas were fabricated. The first antenna was produced (with a photoluminescent efficiency of approximately 30%) and employed a 2000 Å-thick film of tris(8-hydroxyquinoline) aluminum (Alq₃). In the second antenna, the Alq₃ (commercially available from TCI America (Portland, Oreg.)) was doped with 1% of the laser dye DCM2 (commercially available from H. W. Sands (Jupiter, Fla.)), increasing the photoluminescent efficiency of the antenna to approximately 70%. The obtained results are shown graphically in FIG. 21. Both antennas absorb light in the blue, and the excitons are randomly oriented. The quantum efficiency was determined as follows: tunable monochromatic light is illuminated on the solar cell and the photocurrent is measured. If the power intensity of the incident monochromatic light is known, then, the dependence of current output on wavelength of illumination can be determined (the quantum efficiency). Absorption profiles were determined using a Cary UV-VIS absorption spectrometer. A thin film of Alq₃ was deposited and its absorption profile was measured by the spectrometer. Evidence that films of Alq₃ are amorphous (and hence its dipole moments and resultant excitons are not oriented) can be found in Brinkmann et al. “Correlation between molecular packing and optical properties in different crystalline polymorphs and amorphous thin films of mer-tris(8-hydroxyquinoline)aluminum(III)” Journal of the American Chemical Society 122 (21), 5147-5157 (2000). The two curves in FIG. 21 that overlap around 600-800 nm are the quantum efficiency curves for the device described in this example. The other curve in FIG. 21 represents the absorption spectrum of an Alq₃ film.

### EXAMPLE 4

The materials used in constructing photovoltaic cells may be optimized. Potential antenna materials include quantum dots and metal nanoparticles embedded in a solid-state semiconductor matrix. Another material that may be useful is the photosynthetic antenna material phycobilisomes. Desirable properties of the phycobilisomes include, but are not limited, to very high photoluminescent efficiency. This feature is important because the antenna must re-radiate into SPP modes. In general, this process occurs faster than re-radiation into free space modes, meaning that an antenna material with 60% photoluminescent efficiency might radiate with much higher efficiency into SPP modes, but a high efficiency starting point is desirable. Phycobilisomes also have high absorption coefficients. As much light as possible needs to be absorbed in the 100-200 nm thick antenna because radiation into SPP modes is mediated by the near field of the emissive dipoles. Consequently coupling efficiencies will decrease in thicker antennas. Phycobilisomes are also highly stable, especially compared to other organic dye materials. An antenna may include phycobilisomes supported in a stabilizing matrix and such a material can be incorporated into a thin film antenna of a photovoltaic cell.

### EXAMPLE 5

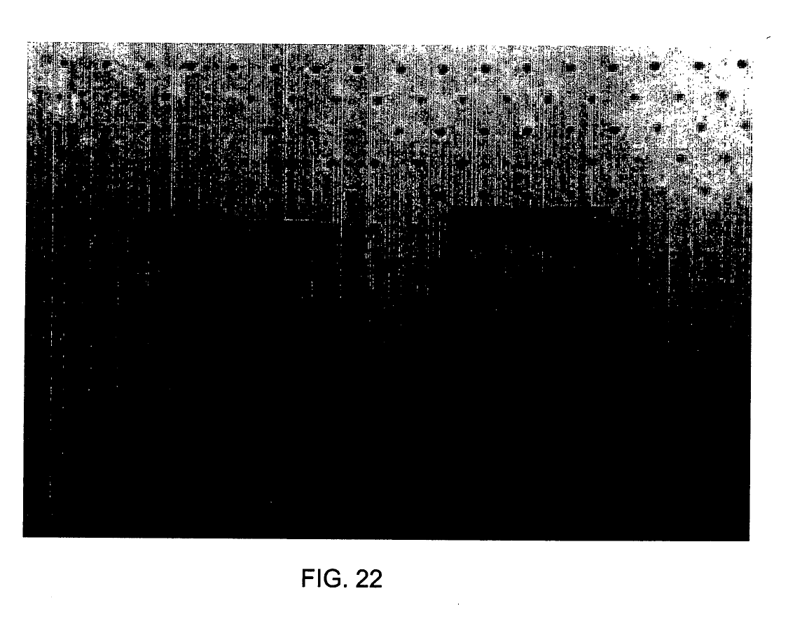

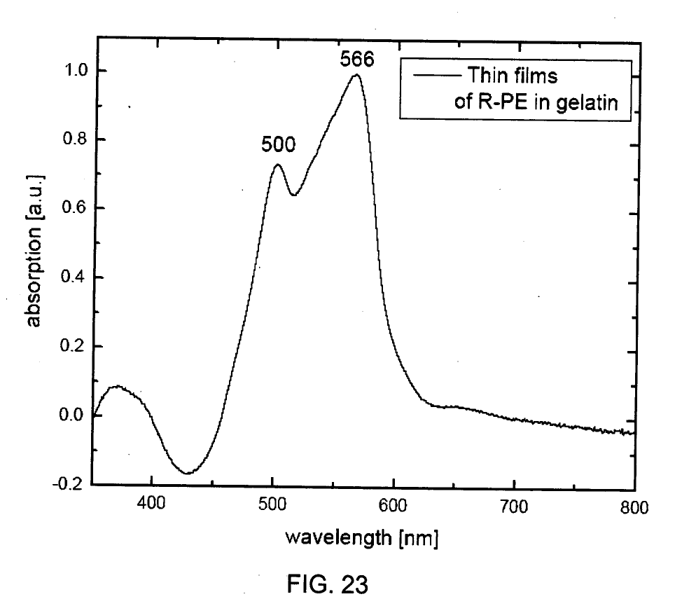

Phycoerythrin may be spun in gelatin and the resulting product may be used as an antenna. Initial results (see FIGS. 22 and 23) spinning phycoerythrin in gelatin showed that the films were not very smooth and scattered more light than was desired. Photographs of two films having a similar composition are shown in FIG. 22. An absorption spectrum of the film is shown in FIG. 23. The absorption spectrum was obtained by subtracting out the scattering background, which can lead to inaccuracies at wavelengths greater than 500 nm.

When introducing elements of the examples disclosed herein, the articles “a,” “an,” “the” and “said” are intended to mean that there are one or more of the elements. The terms “comprising,” “including” and “having” are intended to be open ended and mean that there may be additional elements other than the listed elements. It will be recognized by the person of ordinary skill in the art, given the benefit of this disclosure, that various components of the examples can be interchanged or substituted with various components in other examples. Should the meaning of the terms of any of the publications referred to herein conflict with the meaning of the terms used in this disclosure, the meaning of the terms in this disclosure are intended to be controlling.

Although certain aspects, examples and embodiments have been described above, it will be recognized by the person of ordinary skill in the art, given the benefit of this disclosure, that additions, substitutions, modifications, and alterations of the disclosed illustrative features, aspects, examples and embodiments are possible.

What is claimed is:

1. A photovoltaic cell comprising:
a first material disposed on a first electrode and effective to generate an exciton upon absorption of electromagnetic energy;
a second material electrically coupled to the first electrode and separated from the first material, the second material effective to receive the generated exciton from the first material; and
a second electrode electrically coupled to the second material and electrically coupled to the first electrode.

2. The photovoltaic cell of claim 1 further comprising a circuit constructed and arranged to receive current generated from the photovoltaic cell.

3. The photovoltaic cell of claim 1 in which the first material is selected from the group consisting of quantum dots, a biologically derived light harvesting composition, a dye, a film, a metal nanoparticle embedded in a solid-state semiconductor matrix, a composition comprising two or more conjugated aromatic rings, a J-aggregate and combinations thereof.

4. The photovoltaic cell of claim 1 in which the second material is selected from the group consisting of Si, GaAs, GaN, SiC, perylene, a perylene derivative, a fullerene, a fullerene derivative, a pthalocyanine, a pthalocyanine derivative, a semiconducting conjugated polymer, a semiconducting conjugated polymer derivative, a biological reaction center and combinations thereof.

5. The photovoltaic cell of claim 1 in which the first electrode and the second electrode each independently is selected from the group consisting of carbon, platinum, gold, copper, a heavily-doped semiconductor, a heavily-doped transparent semiconductor, a carbon nanotube, a semiconducting nanowire and combinations thereof.

6. The photovoltaic cell of claim 1 further comprising an optical element configured to direct electromagnetic energy to the first material.

7. The photovoltaic cell of claim 1 in which the second material is effective to separate the received, generated exciton into positive and negative charge carriers to provide a current.

8. A photovoltaic cell comprising an electromagnetic energy absorbing component and a reaction center separate from the electromagnetic energy absorbing component and configured to receive energy from the electromagnetic energy absorbing component to generate a current.

9. The photovoltaic cell of claim 7 in which the electromagnetic energy absorbing component is selected from the group consisting of quantum dots, a biologically derived light harvesting composition, a dye, a film, a metal nanoparticle embedded in a solid-state semiconductor matrix, a composition comprising two or more conjugated aromatic rings, a J-aggregate and combinations thereof.

10. The photovoltaic cell of claim 7 in which the reaction center comprises a material selected from the group consisting of Si, GaAs, GaN, SiC, perylene, a perylene derivative, a fullerene, a fullerene derivative, a pthalocyanine, a pthalocyanine derivative, a semiconducting conjugated polymer, a semiconducting conjugated polymer derivative, a biological reaction center and combinations thereof.

11. The photovoltaic cell of claim 7 further comprising a first conductive material and a second conductive material, in which the reaction center is between the first conductive material and the second conductive material, the first conductive material is between the electromagnetic energy absorbing component and the reaction center, and the first conductive material and the second conductive material are electrically coupled.

12. The photovoltaic cell of claim 11 in which the reaction center is configured to receive an exciton from the electromagnetic energy absorbing component and separate the exciton into positive and negative charge carriers such that a current may flow between the first conductive material and the second conductive material.

13. A solar panel comprising a plurality of photovoltaic cells in which at least one of the photovoltaic cells comprises the photovoltaic cell of claim 7.

14. A power system comprising the photovoltaic cell of claim 1 and a circuit electrically coupled to the photovoltaic cell of claim 1, wherein the circuit is constructed and arranged to receive current from the photovoltaic cell.

15. The power system of claim 14 wherein the circuit receiving the current comprises a charge converter electrically coupled to the photovoltaic cell and electrically coupled to a battery.

16. The power system of claim 14 further comprising an inverter electrically coupled to the battery and configured to provide an AC current from a DC current.

17. A power system comprising the photovoltaic cell of claim 7 and a circuit electrically coupled to the photovoltaic cell of claim 7, wherein the circuit is constructed and arranged to receive current from the photovoltaic cell.

18. The power system of claim 17 wherein the circuit receiving the current further comprises a charge converter electrically coupled to the photovoltaic cell and electrically coupled to a battery.

19. The power system of claim 18 further comprising an inverter electrically coupled to the battery and configured to provide an AC current from a DC current.

20. The power system of claim 17 further comprising a first conductive material and a second conductive material, in which the reaction center is between the first conductive material and the second conductive material, the first conductive material is between the electromagnetic energy absorbing component and the reaction center, and the first conductive material and the second conductive material are electrically coupled, and in which the reaction center is configured to receive an exciton from the electromagnetic energy absorbing component and separate the exciton into positive and negative charge carriers such that a current may flow between the first conductive material and the second conductive material.

21. A method of generating a current with a photovoltaic cell comprising:
transferring an exciton produced from absorption of electromagnetic energy to a reaction center; and
generating a current in the reaction center by separating positive and negative charge constituents of the transferred exciton.

22. The method of claim 21 further comprising configuring the reaction center to receive energy from one or more guided surface plasmon polaritons modes of the exciton.

23. The method of claim 21 further comprising absorbing the electromagnetic energy with an antenna that converts the electromagnetic energy into an exciton.
